(19) United States
(12) Patent Application Publication
(10) Pub. No.: US 2006/0084259 A1
(43) Pub. Date: Apr. 20, 2006

(54) Manufacturing method of passivation layer on wafer and manufacturing method of bumps on wafer

(75) Inventor: Meng-Jin Tsai, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/245,175

(22) Filed: Oct. 7, 2005

(30) Foreign Application Priority Data
Oct. 14, 2004 (TW) 093131103

(51) Int. Cl. H01L 21/60

(52) U.S. Cl. 438/613; 438/614; 438/781

(57) ABSTRACT

A manufacturing method of wafer passivation layer and manufacturing method of wafer bump. First, a wafer is provided with an active surface, which has a passivation layer and reveals a plurality of bonding pads on said passivation. Next, a redistribution layer is formed on the wafer and is electrically connected with the bonding pad. Further, a dielectric layer is formed on the wafer to cover the redistribution layer. Then, said dielectric layer is cured, followed by a patterning process, so that part of the redistribution layer can be revealed from the passivation. Next, plasma cleaning is performed on the active surface of the wafer, and the dielectric layer is cured again. Further, a bumping process is performed. This manufacturing method of wafer passivation and manufacturing method of wafer bump can effectively reduce potential damages of the passivation in further processing procedures and enhance yields.

The present application is based on, and claims priority from, Taiwanese Patent Application Number 093131103, filed Oct. 14, 2004, the disclosure of which is incorporated by reference herein in its entirety.

### BACKGROUND OF THE INVENTION

1. Field of the Invention

The present invention relates to a semiconductor processing, and more particularly to a manufacturing method of wafer passivation and manufacturing method of wafer bump.

2. Description of the Related Art

In recent years, with rapid innovation of electronic technology and the thriving semiconductor industry, electrical devices featuring human-friendliness and multifunction have been constantly launched, altogether toward the trend of being lighter, thinner, and smaller. The fabrication of integrated circuits (IC) mainly includes three stages: IC design, IC manufacturing, and IC packaging. Bare chips are made by procedures from wafer fabrication, circuit design, mask making and wafer sawing. Each bare chip cut from the wafer sawed is electrically connected with external signals via bonding pads disposed on the bare chip. Further, sealing materials are used to capsule the bare chip in order to block impacts from variations in humidity, heat, and noise, as well as to provide a media for electrical connection between the bare chip and external circuits, such as printed circuit board (PCB) or other substrate for packaging.

The common die bonding approaches of prior arts include wire bonding, flip chip bonding, and so on. Due to different junction methods, corresponding bonding pad distributions should be provided in IC fabrication. Commonly used wire bonding chip, for example, features bonding pads disposed in peripheral type, so as to be electrically connected with the junction on the substrate via leads; yet flip chip has its bonding pads arranged in array type and is connected to the junction on the substrate by the bump's electrical and mechanical characteristics.

It can be understood, therefore, that re-distribution or rearrangement of electrical components of the lower layer may be necessary in consequence of changed package type, so as to support different die bonding methods. However, such tremendous effort to modify circuit distribution only incurs chips with similar functionalities, lagging in cost efficiency. Therefore, a redistribution technology of bonding pad is further developed. This technology relates to a redistribution layer allocated on the chip surface, so as to facilitate re-distribution of chip bonding pads as per the junction method applied. For example, chip originally applied to wire bonding can be disposed with a redistribution layer on the surface, so as to transform the peripheral type of bonding pads into array distribution that is suitable for flip chip bonding.

FIG. 1 is the cross sectional view of a flip chip of prior art. The flip chip of prior art first provides a wafer 110, which has an active surface 110a, on which a plurality of bonding pads 112 and a passivation 114 are disposed. And the passivation layer 114 exposes the bonding pad 112. Then, patterning is performed on wafer 110 to form a redistribution layer 120, which is disposed on the passivation 114 and electrically connected with bonding pad 112. Next, a dielectric layer 130 is formed on wafer 110 to cover redistribution layer 120. Afterwards, dielectric layer 130 is cured. Then, patterning is performed on the dielectric layer 130 to form a plurality of openings 130a, which exposes part of the redistribution layer 120. Then, plasma is applied to clean the active surface 110a of wafer 110. Finally, a bumping process is performed to form the under bump metallurgy (UBM) 140 and bump 150 on the exposed redistribution layer 120 of opening 130a.

Please notice that the afore-mentioned plasma cleaning procedure is aimed to clean up any residue of dielectric layer 130 that may remain inside opening 130a. The purpose is to facilitate further bumping process. However, although plasma cleaning may effectively remove residue of dielectric layer 130 inside opening 130a, outside the opening 130a, the cured dielectric layer 130 surface may also be flushed away by the plasma and thereby expose the half-cured parts inside. Therefore, in following bumping processes in which solvents such as detergent and flux are applied, incompletely cured parts of dielectric layer 130 may be easily removed by the solvent and hence defect 132 may be formed. Therefore, redistribution layer 120 may not be effectively protected by dielectric layer 130 and become exposed to oxidation or external humidity that may enter the redistribution layer 120 through defect 132, causing shortage of the internal circuit.

### SUMMARY OF THE INVENTION

It is an object of the present invention to provide a manufacturing method of wafer passivation that can effectively prevent damages from the passivation layer for enhanced yields.

It is another object of the present invention to provide a manufacturing method of wafer bump that can effectively prevent damages to passivation layer for enhanced yields.

To achieve the above and other objects, the present invention proposes a manufacturing method of wafer passivation, which is suitable for a wafer with an active surface, on which a plurality of bonding pads and a passivation that exposes the bonding pad are disposed. First, a redistribution layer is formed on the passivation and bonding pad, and said redistribution layer is electrically connected with bonding pad. Then, a dielectric layer is formed on the wafer to cover the redistribution layer. Further, a first curing process is performed to cure the dielectric layer. Then, patterning is performed on the dielectric layer so that the dielectric layer exposes part of the redistribution layer. Then, a cleaning process is performed on the dielectric layer of the wafer. Then, a second curing process is performed to cure the dielectric layer again.

To achieve the above and other objects, this invention further proposes a manufacturing method of wafer bump. First, a wafer, for example, has an active surface, on which a plurality of bonding pads and a passivation, which exposes the bonding pad, are disposed. Then, a redistribution layer is formed on the passivation layer and bonding pad, which is electrically connected with redistribution layer. Afterwards, form a dielectric layer on the wafer to cover redistribution layer. Then, a first curing process is performed to cure the dielectric layer. The, patterning is performed on dielectric layer so that the dielectric layer exposes part of the redistribution layer. Then, a cleaning process is performed on said dielectric layer of the wafer. A second curing process is performed to cure dielectric layer again. Afterwards, a bumping process is performed on partial areas of the exposed redistribution layer of dielectric layer.

The manufacturing method of wafer bump of this invention, after finishing bumping process, further includes a singulating process performed to form a plurality of independent flip chips. Besides, the above-mentioned bumping process may form a plurality of under bump metallurgies (UBM) on part of the redistribution layer that is exposed by the dielectric layer. Then, a bump is formed on each under bump metallurgy (UBM).

In the manufacturing method of wafer passivation and manufacturing method of wafer bump of present invention, first curing process and second curing process may undergo thermal processing and/or photochemical processing, which may be UV curing. Besides, the above-mentioned dielectric layer may be made of polyimide or benzo-cyclo-butene (BCB) and so on. Further, the afore-mentioned cleaning process may be plasma cleaning.

According to the above, manufacturing method of wafer passivation and manufacturing method of wafer bump of the present invention include another curing on the dielectric layer after plasma cleaning, so as to enhance the surface strength of dielectric layer, and reduce the occurrence that the dielectric layer is damaged in the following bumping processes duce to reaction with the solvent and yields may be enhanced.

Other objects, advantages, and novel features of the present invention will become more apparent from the following detailed description of the preferred embodiments when taken in conjunction with the accompanying drawings.

### BRIEF DESCRIPTION OF THE DRAWINGS

FIG. 1 is a cross sectional view of a flip chip of prior art.

FIG. 2A˜2H respectively illustrates a manufacturing method of a wafer bump according to preferred embodiment of the present invention.

FIG. 3 is the production flow-chart of the wafer bump of the present invention.

### DETAILED DESCRIPTION OF THE PREFERRED EMBODIMENT

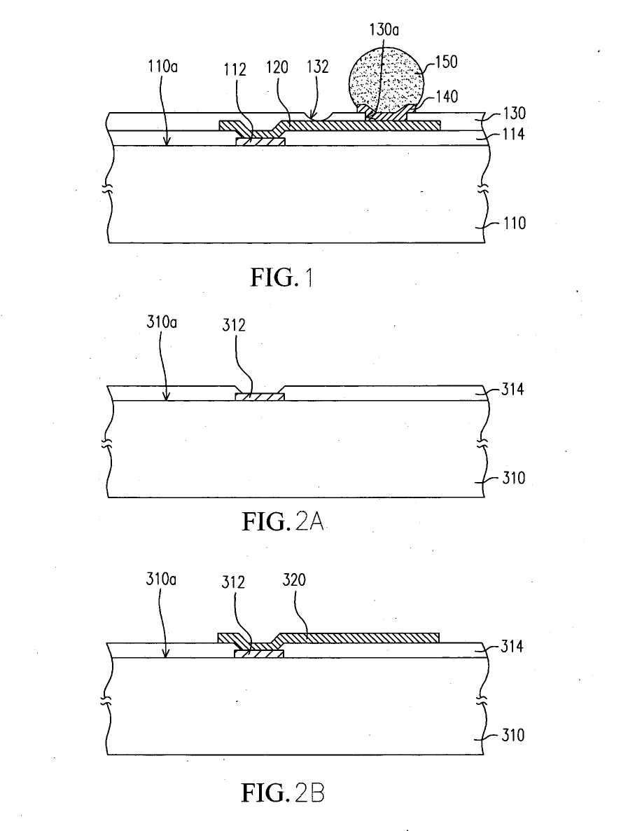

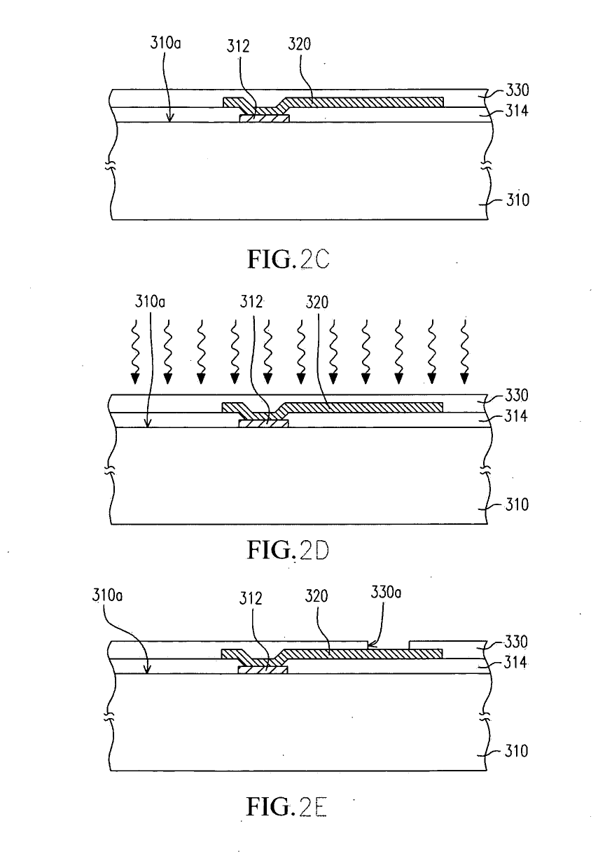

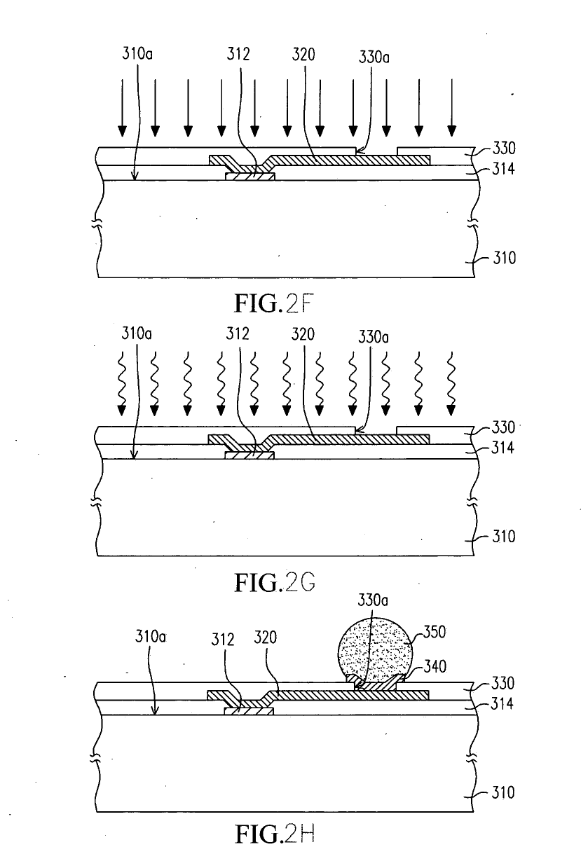

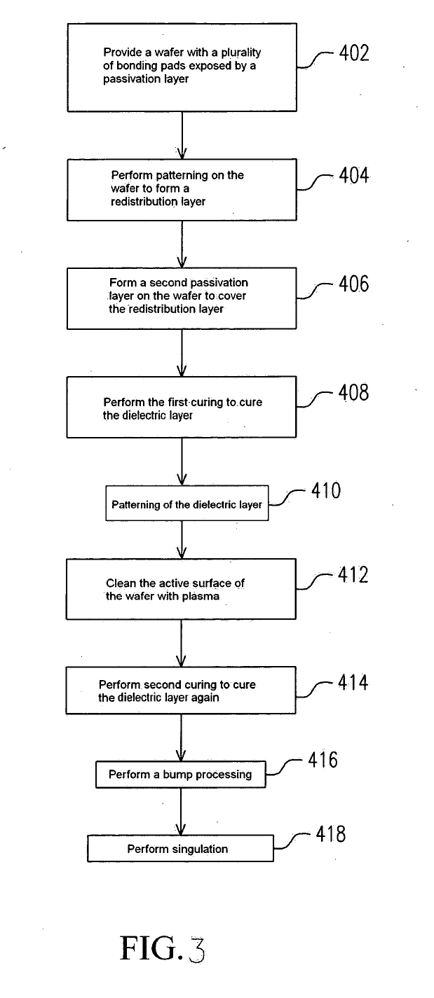

Referring FIG. 2A˜2H and FIG. 3, FIG. 2A˜2H respectively illustrates a manufacturing method of a wafer bump according to preferred embodiment of the present invention. And FIG. 3 is the production flow-chart of the wafer bump of the present invention.

First, as shown in FIG. 2A, a wafer 310 (Step 402), for example, composed of a plurality of bare chips (not illustrated) are provided. However, to simplify the diagram, this embodiment only illustrates the cross sectional view of part of the wafer. wafer 310 may have an active surface 310a, on which a plurality of bonding pads 312 may be disposed (only one is illustrated), and a passivation 314 that exposes the bonding pad 312.

Further, as shown in FIG. 2B, a redistribution layer 320 is formed by patterning on wafer 310 (Step 404). Here, redistribution layer 320 is disposed on said passivation layer 314 and is electrically connected with bonding pad 312 exposed by said passivation layer 314.

Then, as shown in FIG. 2C, a dielectric layer 330 is formed on wafer 310 to cover redistribution layer 320 (Step 406). Here, material of said dielectric layer 330, for example, can be adequate organic materials such as polyimide or benzo-cyclo-butene (BCB).

Then, as shown in FIG. 2D, the first curing process is performed to cure the dielectric layer 330 (Step 408). Here, methods to cure said dielectric layer 330 include thermal processing and/or photochemical processing, and thermal processing may be conducted with heading in a scalar heating model or rapid heating model; and the photochemical processing may be UV curing. In the preferred embodiment, high temperature of 350° C.˜400° C. is applied for the baking of said dielectric layer 330 in duration of 10 minutes to 2 hours. In another preferred embodiment, under the temperature of 25° C.˜250° C., said dielectric layer 330 may be exposed to ultraviolet for a duration of 30 seconds to 10 minutes.

Then, as shown in FIG. 2E, patterning is executed on said dielectric layer 330 (Step 410) to form a plurality of openings 330a (only one is illustrated), which exposes part of the redistribution layer 320. When the dielectric layer 330 is made of photographic material, patterning dielectric layer 330 may adopt steps of exposure and developing. On the other hand, if the dielectric layer 330 is not made of photographic material, photoresistant material (liquid photoresist or dry film) may be applied as mask for the patterning, so as to facilitate the procedure of etching on dielectric layer 330.

Then, as shown in FIG. 2F, plasma is used in the cleaning of active surface 310a of said wafer 310 (Step 412) to clean residue of dielectric layer 330 left in opening 330a, and plasma may also remove other parts of dielectric layer 330 surface else than opening 330a.

Further, as shown in FIG. 2G, a second curing process is performed to cure dielectric layer 330 again (Step 414). This will cure all the incompletely cured yet exposed parts in dielectric layer 330. Here, the curing process may be identical to Step 408 and curing of dielectric layer 330 may also include thermal processing or photochemical processing. Details are provided in Step 408.

Then, as shown in FIG. 2H, a bumping process (Step 416) is performed to form a plurality of under bump metallurgies (UBM) on parts of redistribution layer 320 exposed by opening 330a (only one is illustrated). And on each under bump metallurgy (UBM) 340, a bump 350 is formed.

Certainly, after the above procedures, as described in Step 418, a singulation process can be performed to extract a plurality of inter-independent flip chips (not illustrated here). The singulation may be performed by sawing or punching of wafer 310.

In sum, this invention proposes a manufacturing method of wafer passivation (as shown in Step 402˜414 of FIG. 3), accompanied with following bumping process and singulating process, to propose a manufacturing method of wafer bump (as Step 402˜418 in FIG. 3). Since this invention includes another curing process after plasma cleaning to cure the incompletely cured parts inside dielectric layer after plasma cleaning, the strength of the dielectric layer surface can be enhanced. Therefore, in the following bumping processes, damages on dielectric layer caused by interaction with solvent in further bumping process may be reduced to achieve better yields.

Although the invention has been explained in relation to its preferred embodiment, it is to be understood that many other possible modifications and variations can be made without departing from the spirit and scope of the invention as hereinafter claimed. Further, the present invention is defined by the patent claims.

What is claimed is:

1. A manufacturing method of wafer bump, said method comprising:
providing a wafer, which has an active surface with a plurality of bonding pads and a passivation formed on the active surface that exposes said bonding pads;
forming a redistribution layer on said passivation and said bonding pads, in which the redistribution layer is electrically connected with the bonding pads;
forming a dielectric layer on said wafer to cover the redistribution layer;
performing a first curing process to cure the surface of said dielectric layer;
patterning on said dielectric layer, so that the dielectric layer reveals parts of the redistribution layer;
performing a plasma cleaning process on the dielectric layer of said wafer;
performing a second curing process to fully cure the whole surface of said dielectric layer; and
performing a bumping process to form a plurality of bumps on parts of the said redistribution layer that is revealed by the dielectric layer.

2. The manufacturing method of wafer bump as claimed in claim 1, wherein after said bumping process, a singulating process is performed to obtain a plurality of chips.

3. The manufacturing method of wafer bump as claimed in claim 1, wherein the bumping process comprises:
forming a plurality of under bump metallurgies (UBM) on partial areas of said redistribution layer revealed by said dielectric layer; and
forming a bump on each of said under bump metallurgy (UBM).

4. The manufacturing method of wafer bump as claimed in claim 1, wherein the first curing process and said second curing processes include a thermal processing.

5. The manufacturing method of wafer bump as claimed in claim 1, wherein the first curing and said second curing processes include a photochemical processing.

6. The manufacturing method of wafer bump as claimed in claim 5, wherein the photochemical processing includes UV curing.

7. The manufacturing method of wafer bump as claimed in claim 1, wherein material of the dielectric layer includes polyimide.

8. The manufacturing method of wafer bump as claimed in claim 1, wherein material of the dielectric layer includes benzo-cyclo-butene (BCB).
